(19) United States
(12) Patent Application Publication
(10) Pub. No.: US 2011/0076389 A1
(43) Pub. Date: Mar. 31, 2011

(54) DEPOSITION SOURCE AND METHOD OF MANUFACTURING ORGANIC LIGHT-EMITTING DEVICE

(75) Inventors: Jung-Min Lee, Giheung-Gu (KR); Choong-Ho Lee, Giheung-Gu (KR); Soo-Jin Park, Giheungi-Gu (KR)

(73) Assignee: SAMSUNG MOBILE DISPLAY CO. LTD., Yongin-City (KR)

(21) Appl. No.: 12/885,259

(22) Filed: Sep. 17, 2010

(30) Foreign Application Priority Data
Sep. 25, 2009 (KR) KR 2009-0091140

(51) Int. Cl. B05D 5/06; F28F 7/00; F28D 15/04

(52) U.S. Cl. 427/66; 165/185; 165/104.26

(57) ABSTRACT

A deposition source which improves deposition characteristics and uniformity of a deposited film, and a method of manufacturing an organic light-emitting device. The deposition source includes a heat source, a heat transfer plate arranged on the heat source and adapted to receive heat generated by and transferred from the heat source and a planarization layer arranged on the heat transfer plate, the heat source to supply more heat per unit area to outer portions of the heat transfer plate that surrounds a central portion of the heat transfer plate than to the central portion of the heat transfer plate.

### CLAIM OF PRIORITY

This application makes reference to, incorporates the same herein, and claims all benefits accruing under 35 U.S.C.§119 from an application earlier filed in the Korean Intellectual Property Office on Sep. 25, 2009 and there duly assigned Ser. No. 10/2009-0091140.

### BACKGROUND OF THE INVENTION

1. Field of the Invention

The present invention relates to a deposition source and a method of manufacturing an organic light-emitting device, and more particularly, to a deposition source which improves deposition characteristics and uniformity of a deposited film.

2. Description of the Related Art

Electronic devices include fine thin films and use various methods to form the fine thin films. Particularly, flat display devices are manufactured by forming a plurality of thin films. Thus, in order to improve the characteristics of flat display devices, the characteristics of the plurality of thin films need to be improved.

Organic light-emitting devices, among flat display devices, have a larger viewing angle, better contrast characteristics, and a faster response rate than other flat display devices, and thus have drawn attention as a next-generation display device. An organic light-emitting layer that emits visible rays from an organic light-emitting device, and organic layers disposed around the organic light-emitting layer are produced using various methods. Particularly, vacuum deposition, which is a simple process, is frequently used to produce the organic layers. In vacuum deposition, a deposition material in a powder or solid state and used in a deposition process is heated to form a deposited film in a desired location.

A dotted deposition source, a linear deposition source or a plate-shaped deposition source can be used in vacuum deposition. When a dotted deposition source is used, a deposition material is dispersed in a wide substrate from the dotted deposition source and thus the uniformity of a deposited film cannot be obtained.

Also, in deposition using the linear deposition source, a powder is put in to a crucible that extends in one direction, and the crucible is heated to form a deposited film. A deposition process is performed while the linear deposition source or the substrate is moved. Thus, uniform deposition characteristics cannot be obtained.

When the plate-shaped deposition source is formed to have the size of a target on which a deposition material is to be deposited, a deposition process may be performed without moving the deposition source or the substrate. In other words, due to the shape of the heat transfer plate, the distribution of temperature of the heat transfer plate is non-uniform according to location on the heat transfer plate, because outer areas of the heat transfer plate in the related art are close to the atmosphere and heat generated in the outer areas of the heat transfer plate is easily dissipated to the outside. As such, the temperature of the outer areas of the heat transfer plate in the related art is lower than central areas thereof. Also, since the temperature of the heat transfer plate is non-uniform according to location on the heat transfer plate, the deposition material in the related art is not uniformly vaporized, and the uniformity of a deposited film formed on the target is reduced.

However, it is difficult to keep a uniform temperature over the entire surface of the target. As a result, it is also difficult to obtain uniform deposition characteristics. In particular, as the size of the target increases, there is a limitation in improving deposition characteristics. What is therefore needed is an improved deposition source that provides uniform temperature throughout the heat transfer plate so that a deposition of a material on a target can be accomplished resulting in more uniform thickness and more uniform characteristics.

### SUMMARY OF THE INVENTION

The present invention provides a deposition source which improves deposition characteristics and uniformity of a deposited film, and a method of manufacturing an organic light-emitting device.

According to an aspect of the present invention, there is provided a deposition source, the deposition source including a heat source, a heat transfer plate arranged on the heat source and adapted to receive heat generated by and transferred from the heat source and a planarization layer arranged on the heat transfer plate, the heat source to supply more heat per unit area to outer portions of the heat transfer plate that surrounds a central portion of the heat transfer plate than to the central portion of the heat transfer plate.

The heat source can include a coil portion. The deposition source can also include a power supply unit, wherein the coil portion is being of a single body that is connected to the power supply unit. The deposition source can also include a plurality of power supply units, wherein the coil portion is comprised of a corresponding plurality of subcoil portions, and wherein ones of the plurality of subcoil portions are connected to separate and independent ones of the plurality of power supply units. Ones of the plurality of subcoil portions of the coil portion can be more compactly arranged at locations corresponding to an outer portion of the heat transfer plate that surrounds a central portion of the heat transfer plate and are less compactly arranged at locations corresponding to the central portion of the heat transfer plate. Ones of the plurality of subcoil portions of the coil portion can be arranged throughout an entirety of the heat transfer plate at a uniform density. The coil portion can be made of nickel or titanium. The heat source can include a heat pipe and a heat transfer fluid arranged within the heat pipe. The heat pipe can have a plurality of coils, wherein ones of the coils of the heat pipe can be more compactly arranged at locations corresponding to an outer portion of the heat transfer plate that surrounds a central portion of the heat transfer plate and are less compactly arranged at locations corresponding to the central portion of the heat transfer plate. The heat pipe can be made out of copper or aluminum. The heat transfer fluid can be a paraffin-based compound. The heat transfer plate can be a metal. The planarization layer can be separable from the heat transfer plate. The planarization layer can be made out of aluminum or copper. The deposition source can also include a heat blocking portion arranged to surround side surfaces of the heat transfer plate and the planarization layer. Portions of the heat blocking portion can be arranged under the heat source. The heat blocking portion can be a ceramic. The heat blocking portion can include ZrO2, SiO2 or CaO. A size of the planarization layer can be larger than a size of a target on which the deposition material is to be deposited.

According to another aspect of the present invention, there is provided a method of manufacturing an organic light-emitting device, including providing a deposition source that includes a heat source, a heat transfer plate arranged on the heat source to receive heat generated by and transferred from the heat source, and a planarization layer arranged on the heat transfer plate, the heat source to supply more heat per unit area of the heat transfer plate to outer portions of the heat transfer plate that surround a central portion of the heat transfer plate than to the central portion of the heat transfer plate, preparing a substrate having a first electrode arranged thereon, forming an organic light-emitting layer on the first electrode, forming at least one organic layer arranged adjacent to the organic light-emitting layer and forming a second electrode electrically connected to the organic light-emitting layer, wherein the deposition source is used to produce at least one of the organic light-emitting layer and the at least one organic layer.

The forming of the at least one of the organic light-emitting layer and the at least one organic layer via the deposition source can include arranging the substrate to face the planarization layer. A size of the planarization layer can be larger than a size of the substrate. The at least one organic layer can include at least one layer selected from a group consisting of a hole injection layer, a hole transport layer, an electron transport layer, and an electron injection layer.

### BRIEF DESCRIPTION OF THE DRAWINGS

A more complete appreciation of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic perspective view of a deposition source according to a first embodiment of the present invention;

FIG. 2 is a cross-sectional view taken along line II-II of FIG. 1;

FIG. 3A is a schematic perspective view of a coil portion of FIG. 2;

FIG. 3B is a schematic perspective view of a modified example of FIG. 3A;

FIG. 4 is a schematic cross-sectional view of a deposition source according to a second embodiment of the present invention;

FIG. 5 is a schematic perspective view of a coil portion of FIG. 4;

FIG. 6 is a schematic cross-sectional view of a deposition source according to a third embodiment of the present invention;

FIG. 7 is a schematic perspective view of a coil portion of FIG. 6;

FIG. 8 is a schematic cross-sectional view of a deposition source according to a fourth embodiment of the present invention;

FIG. 9 is a schematic perspective view of a heat pipe of FIG. 8; and

FIGS. 10A through 10F are cross-sectional views illustrating a method of manufacturing an organic light-emitting device according to an embodiment of the present invention.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

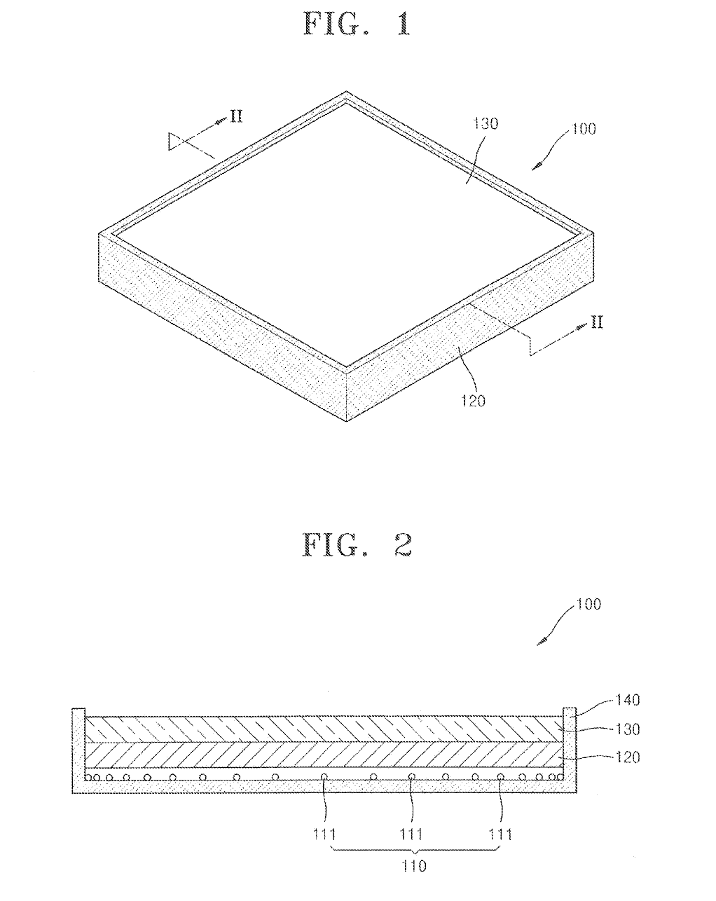

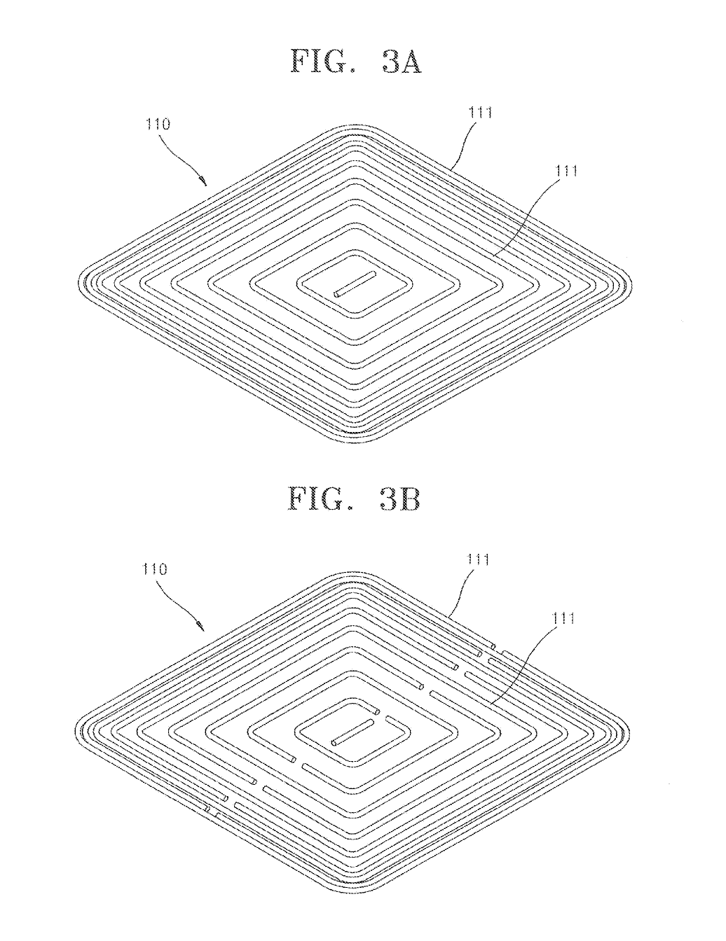

FIG. 1 is a schematic perspective view of a deposition source 100 according to a first embodiment of the present invention, FIG. 2 is a cross-sectional view taken along line II-II of FIG. 1, and FIG. 3A is a schematic perspective view of a coil portion 110 of FIG. 2. Referring to FIGS. 1 through 3A, the deposition source 100 includes a heat source (not shown) including the coil portion 110, a heat transfer plate 120, a planarization layer 130, and a heat blocking portion 140.

The deposition source 100 is disposed in a chamber (not shown), and a target (not shown) on which a deposition material is to be deposited is disposed in the chamber to face the deposition source 100. The chamber is connected to one or more pumps (not shown) so that the chamber may be kept in a vacuum state or under low pressure. Also, one or more outlets (not shown) through which the target is entered or removed are disposed at a side surface of the chamber.

The deposition source 100 is disposed with respect to the target in such a way that a deposition material may be deposited over the entire surface of the target. To this end, the size of the deposition source 100 may be larger than the size of the target.

The heat source may be a heating device in various shapes that heats the deposition material disposed at an upper portion of the planarization layer 130. In the first embodiment, the heat source includes the coil portion 110 which includes a plurality of subcoil portions 111. As illustrated in FIG. 3A, the subcoil portions 111 have essentially a rectangular shape, and the sizes of the subcoil portions 111 are different.

The subcoil portions 111 are separated from each other. The separated subcoil portions 111 are each connected to different and independent power supply units (not shown). As a result, the magnitude of a voltage applied to each of the subcoil portions 111 may be independently controlled. The subcoil portions 111 may be made out of various metal materials such as nickel or titanium.

Also, the coil portion 110 is disposed so that the outer subcoil portions 111 of the coil portion 110 may be more compactly arranged than the central subcoil portions 111 thereof. In other words, the outer subcoil portions 111 of the coil portion 110 are not disposed at equal intervals but are disposed so that an interval neighboring ones of the subcoil portions arranged furthest away from a center of the heat transfer plate 120 is smaller than an interval between neighboring ones of subcoil portions 111 to located near a center of the heat transfer plate 120. Thus, heat generated per unit area by the subcoil portions 111 of the coil portion 110 may vary with location on the heat transfer plate 120.

Referring to FIG. 3A, each of the subcoil portions 111 has a similar shape to a rectangle, however, the present invention is not limited thereto. In other words, the subcoil portions 111 are disposed in such a way that, when the subcoil portions 111 are spaced apart from each other, an interval between the outermost subcoil portions 111 is smaller than an interval between the central subcoil portions 111. FIG. 3B is a schematic perspective view of a modified example of FIG. 3A. Referring to FIG. 3B, the subcoil portions 111 may have a similar shape to a rectangle or a rectangular shape with ends separate from each other.

The heat transfer plate 120 is disposed on the coil portion 110. The heat transfer plate 120 is made out of a material having a good heat transfer efficiency so as to easily transfer heat generated by the coil portion 110. To this end, the heat transfer plate 120 is made out of a metal that may include aluminum (Al) or anodized aluminum, for example, so as to improve heat transfer efficiency and durability of the heat transfer plate 120.

In FIG. 1, the heat transfer plate 120 and the coil portion 110 are separated from each other, however, the present invention is not limited thereto, and the coil portion 110 and the heat transfer plate 120 may contact each other. In other words, heat may be transferred to the heat transfer plate 120 from the coil portion 110 according to conduction. The heat transfer plate 120 affects the durability of the deposition source 100 and thus has a thickness of several mm or more.

The planarization layer 130 is disposed on the heat transfer plate 120. A deposition material that is used to form a deposited film on the target is disposed on the planarization layer 130. To this end, the planarization layer 130 is produced to have a high degree of planarization. An adhesion layer is not interposed between the planarization layer 130 and the heat transfer plate 120 so that the planarization layer 130 may be easily separated from the heat transfer plate 120. In other words, the planarization layer 130 may be disposed on the heat transfer plate 120 by using only the weight of the planarization layer 130. When the weight of the planarization layer 130 is low, an additional weight (not shown) may be disposed at an upper edge of the planarization layer 130.

The deposition material is put on the planarization layer 130 and may be in a liquid or powder form. Since the planarization layer 130 is easily separated from the heat transfer plate 120, the deposition material may be easily put on the planarization layer 130, and unused deposition material that remains on upper portions of the planarization layer 130 may be easily removed after a deposition process is performed.

The planarization layer 130 is made out of a metal and may include aluminum or copper that has good thermal conductivity. For example, the planarization layer 130 may be made out of anodized aluminum. The size of the planarization layer 130 may be larger than the size of the target on which the deposition material is to be deposited.

The heat blocking portion 140 is disposed surrounding side surfaces of the heat transfer plate 120 and the planarization layer 130. Also, the heat blocking portion 140 arranged under the coil portion 110. As a result, heat generated by the coil portion 110 is transferred to the heat transfer plate 120 as opposed to being dissipated into the atmosphere by peripheral portions of the coil portion 110. Also, heat transferred to the planarization layer 130 may be efficiently transferred to the deposition material so that the efficiency of the deposition process may be improved.

The heat blocking portion 140 is made out of a material having an excellent adiabatic characteristic and may be made out of a ceramic-based material. In detail, the heat blocking portion 140 can be made out of at least one of ZrO2, SiO2, and CaO.

The deposition source 100 according to the first embodiment is shaped as a plate and its size is larger than the size of the target. Thus, a deposition process is performed at one time without moving the deposition source 100 or the target, so that a desired deposited film may be formed on the target.

Also, the deposition source 100 according to the first embodiment includes the coil portion 110 including the separated subsoil portions 111. Thus, the whole temperature of the heat transfer plate 120 may be uniform.

In other words, in the related art, due to the shape of the heat transfer plate, the distribution of temperature of the heat transfer plate is non-uniform according to location on the heat transfer plate, because outer areas of the heat transfer plate in the related art are close to the atmosphere and heat generated in the outer areas of the heat transfer plate is easily dissipated to the outside. As such, the temperature of the outer areas of the heat transfer plate in the related art is lower than central areas thereof. Also, since the temperature of the heat transfer plate is non-uniform according to location on the heat transfer plate, the deposition material in the related art is not uniformly vaporized, and the uniformity of a deposited film formed on the target is reduced.

However, the subcoil portions 111 of the coil portion 110 of the deposition source 100 of the first embodiment of the present invention are arranged at different intervals according to different areas of the heat transfer plate 120. In other words, a relatively large number of the subcoil portions 111 are arranged at the outer portion of the heat transfer plate 120, and a relatively small number of the subcoil portions 111 are arranged at the central portion of the heat transfer plate 120. Specifically, an interval between neighboring ones of the subsoil portions 111 located at the outer portion of the heat transfer plate 120 is smaller than an interval between neighboring ones of subcoil portions 111 located near the center of the heat transfer plate 120. By designing the subcoil portions 111 this way, a relatively large amount of heat may be transferred to the outer portion of the heat transfer plate 120 as compared to the central portion of the heat transfer plate 120 to offset the additional cooling by the atmosphere found at the outer portions of the heat transfer plate 120. As a result, non-uniformity of temperature of the heat transfer plate 120 may be prevented, and uniformity of deposition on the target may be achieved.

Furthermore, each of the subcoil portions 111 is connected to different independently controlled power supply units. As a result, the subcoil portions 111 may be each independently controlled. Thus, heat transferred to the heat transfer plate 120 may be finely controlled according to areas of the heat transfer plate 120. By doing so, the uniformity of distribution of temperature of the heat transfer plate 120 according to different locations on the heat transfer plate 120 may be improved, and uniformity of deposition may be improved.

Also, the deposition material to be discharged from the deposition source 100 is put on the planarization layer 130. The planarization layer 130 is easily separated from the heat transfer plate 120 so that a process of putting the deposition material on the planarization layer 130 and a process of removing the deposition material from the planarization layer 130 may be easily performed.

Also, the heat blocking layer 140 prevents heat generated by the coil portion 110 from being dissipated to the atmosphere so that the heat can instead be sequentially transferred to the heat transfer plate 120 and the planarization layer 130 so that deposition efficiency may be improved.

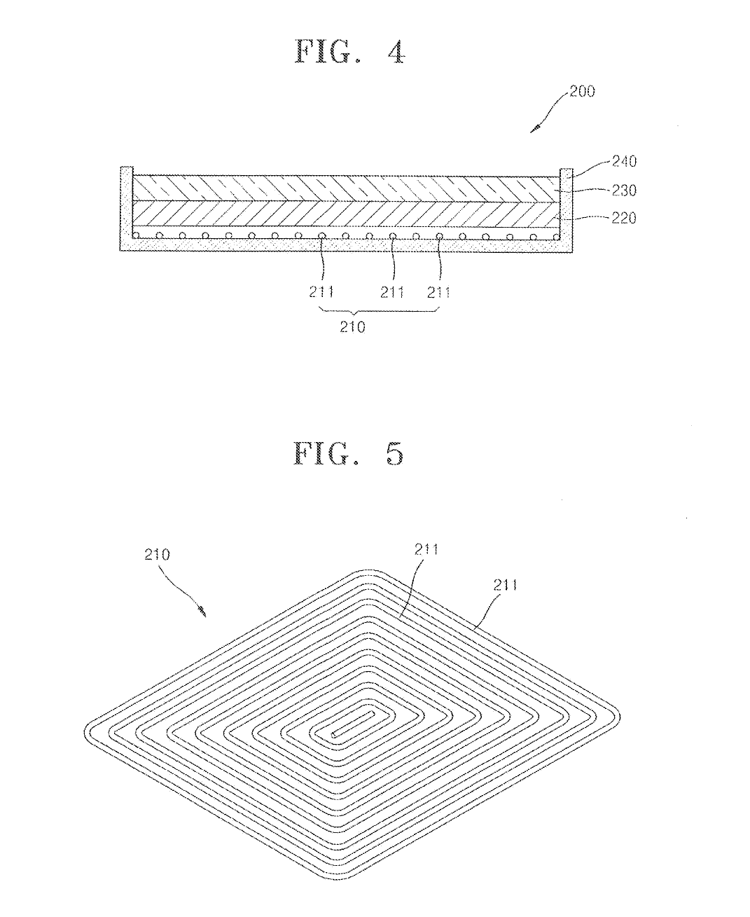

FIG. 4 is a schematic cross-sectional view of a deposition source 200 according to a second embodiment of the present invention, and FIG. 5 is a schematic perspective view of a coil portion 210 of FIG. 4. For convenience of explanation, only differences between the second embodiment and the first embodiment will now be described.

Referring to FIG. 4, the deposition source 200 according to the present embodiment includes a heat source (not shown) including the coil portion 210, a heat transfer plate 220, a planarization layer 230, and a heat blocking portion 240. The configuration of the deposition source 200 is similar to that of the deposition source 100 of FIGS. 1 through 3, except for the coil portion 210, and thus, only the coil portion 210 will now be described.

The coil portion 210 includes a plurality of subcoil portions 211. Each of the subcoil portions 211 has a similar shape to a rectangle, and the sizes of ones of the subcoil portions 211 are different from each other.

The subcoil portions 211 are separated from each other. The separated subcoil portions 211 are each connected to separate power supply units so that each subcoil portion 211 can be independently controlled. Thus, the magnitude of a voltage applied to each of the subcoil portions 211 may be controlled.

The subcoil portions 211 are arranged throughout the entire region of the heat transfer plate 220 at the same density. In detail, the subcoil portions 211 are arranged at equal intervals throughout the heat transfer plate 220. Each of the subcoil portions 211 is connected to an independent power supply unit, and thus heat generated in each of the subcoil portions 211 may be independently controlled. As a result, a relatively large amount of heat may be transferred to the outer areas of the heat transfer plate 220 than to the central areas of the heat transfer plate 220. Thus, non-uniformity of temperature of the heat transfer plate 200 may be prevented, and uniformity of deposition on the target may be improved.

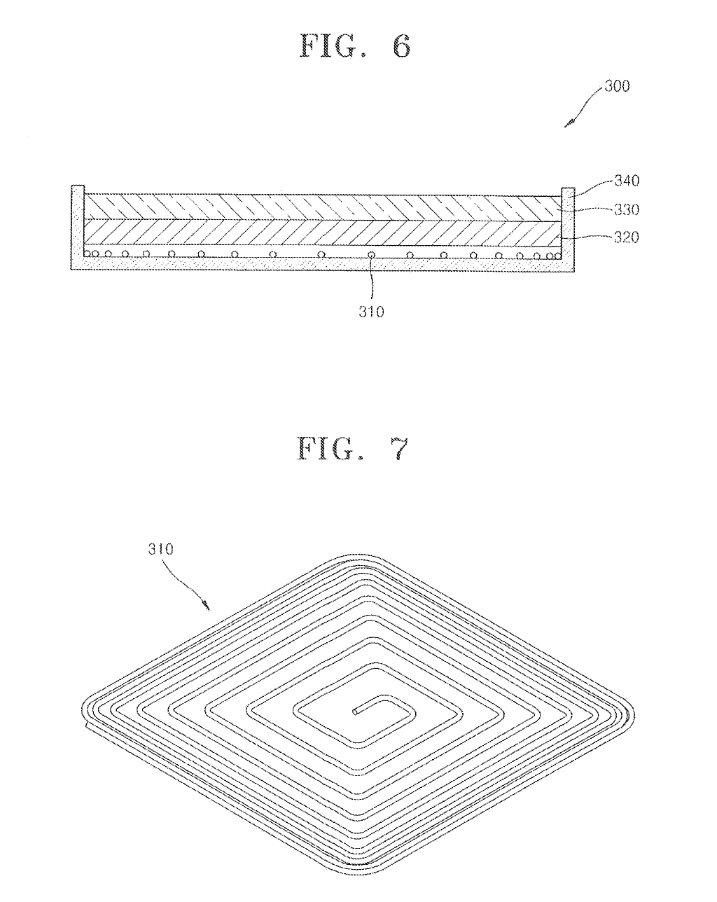

FIG. 6 is a schematic cross-sectional view of a deposition source 300 according to a third embodiment of the present invention, and FIG. 7 is a schematic perspective view of a coil portion 310 of FIG. 6. For convenience of explanation, only a difference between the third embodiment and the previous embodiments will now be described.

Referring to FIG. 6, the deposition source 300 according to the third embodiment includes a heat source including the coil portion 310, a heat transfer plate 320, a planarization layer 330, and a heat blocking portion 340.

The configuration of the deposition source 300 is similar to that of the deposition source 100 of FIGS. 1 through 3, except for the coil portion 310, and thus, only the coil portion 310 will now be described.

The coil portion 310 is formed as a single body and is connected to a single power supply unit (not shown). As a result, spacing between neighboring ones of the coils of the coil portion 310 are arranged at different intervals. In other words, the coils of the coil portion 310 are more compactly arranged at locations corresponding to the outer portion of the heat transfer plate 320 and are less compactly arranged at locations corresponding to the center of the heat transfer plate 320. Specifically, an interval between the outer coils of the coil portion 310 corresponding to the outer portion of the heat transfer plate 320 is smaller than an interval between the central coils of the coil portion 310 corresponding to the center of the heat transfer plate 320. As such, a relatively large amount of heat per unit area may be transferred to the outer portion of the heat transfer plate 320 than to the center thereof. Thus, non-uniformity of temperature of the heat transfer plate 320 may be prevented, and uniformity of deposition on the target may be improved.

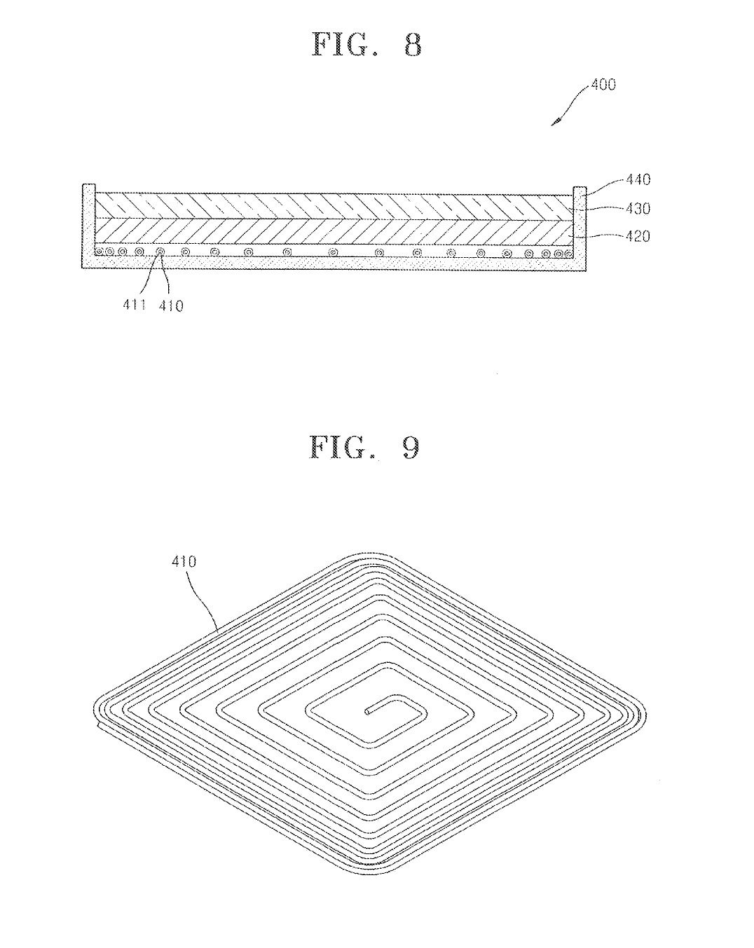

FIG. 8 is a schematic cross-sectional view of a deposition source 400 according to fourth embodiment of the present invention, and FIG. 9 is a schematic perspective view of a heat pipe 410 of FIG. 8. For convenience of explanation, only a difference between the fourth embodiment and the previous embodiments will now be described.

Referring to FIG. 8, the deposition source 400 according to the fourth embodiment includes a heat source (not shown) including the heat pipe 410, a heat transfer plate 420, a planarization layer 430, and a heat blocking portion 440.

The configuration of the deposition source 400 is similar to that of the deposition source 100 of FIGS. 1 through 3, except for the heat pipe 410, and thus, only the heat pipe 410 will now be described.

The deposition source 400 includes the heat source including the heat pipe 410 in which a heat transfer fluid 411 is disposed within. The heat transfer fluid 411 is circulated via the heat pipe 410, and heat is transferred to the heat pipe 410 from to the heat transfer fluid 411, and then the heat is transferred to the heat transfer plate 420.

The heat transfer fluid 411 may be made out of a material having good heat transfer efficiency, for example a paraffin-based compound. Also, the heat pipe 410 may be made out of a include metal so that heat may be easily transferred from the heat transfer fluid 411. Specifically, the heat pipe 410 may be made out of copper (Cu) or aluminum (Al).

In this case, coils of the heat pipe 410 are arranged at different intervals therebetween. In detail, coils of the heat pipe 410 are more compactly arranged at locations corresponding to the outer portion of the heat transfer plate 420, and coils of the heat pipe 410 are relatively less compactly arranged at locations corresponding to the center of the heat transfer plate 420. Specifically, an interval between the outer coils of the heat pipe 410 corresponding to the outer portion of the heat transfer plate 420 is smaller than an interval between coils of the heat pipe 410 corresponding to the center of the heat transfer plate 420. As such, more heat per unit area may be transferred to the outer portion of the heat transfer plate 420 than to the center portion of the heat transfer plate 420. Thus, non-uniformity of temperature of the heat transfer plate 420 may be prevented, and uniformity of deposition on the target may be improved.

The deposition source 400 may be used to deposit a thin film that is used in various aspects. As a specific example thereof, the deposition source 400 may be used to manufacture an organic light-emitting device.

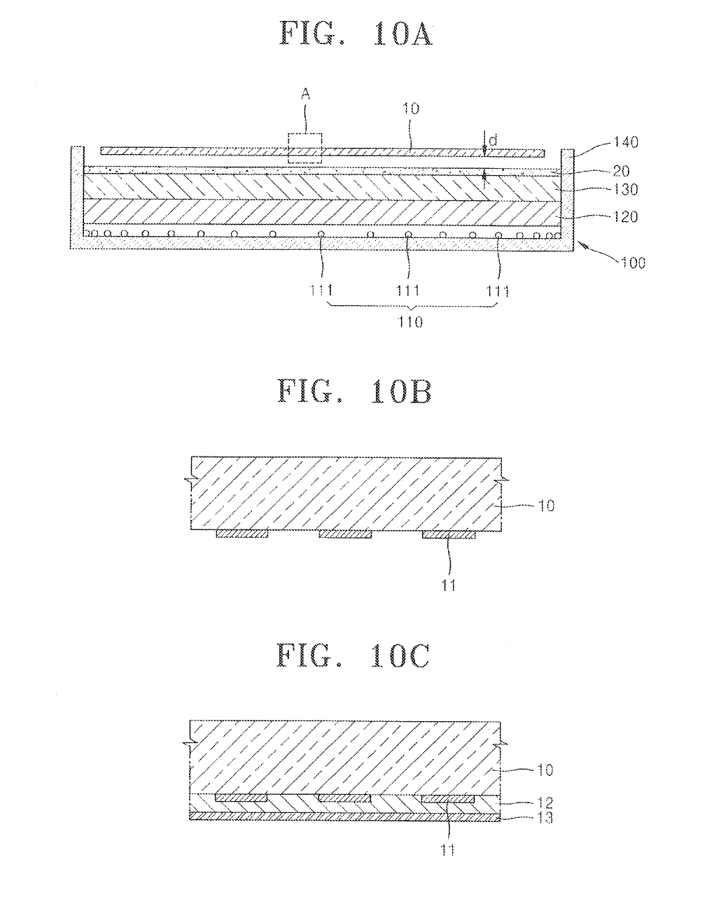

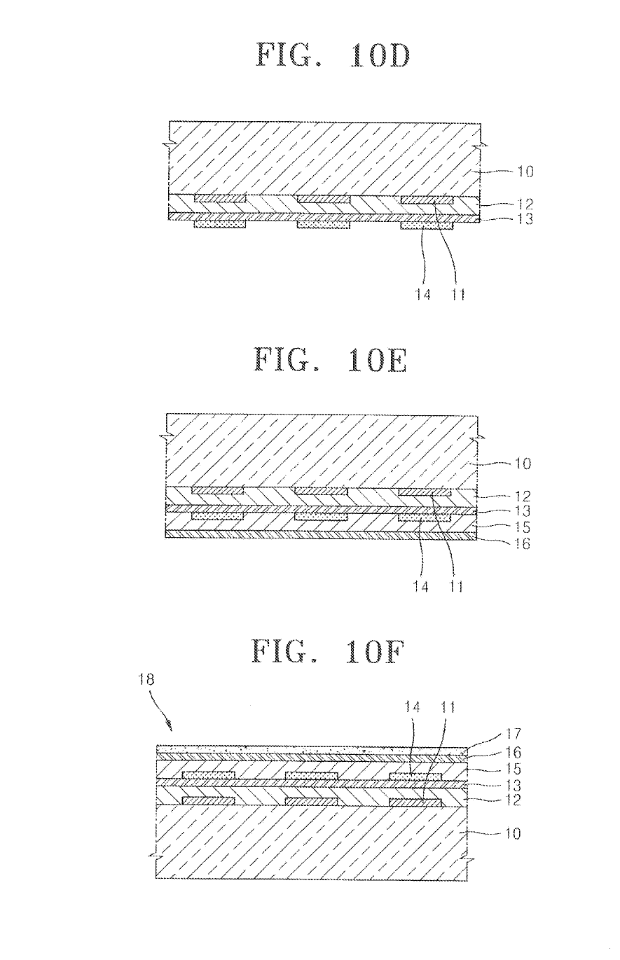

FIGS. 10A through 10F are cross-sectional views illustrating a method of manufacturing an organic light-emitting device 18 according to an embodiment of the present invention. Referring to FIG. 10A, a substrate 10 is disposed facing the deposition source 100 of FIG. 1. FIG. 10B is an enlarged view of a portion A of FIG. 10A. A first electrode 11 is disposed on the substrate 10. Although not shown, the deposition source 100 and the substrate 10 are disposed in a chamber (not shown), and the chamber is kept at a vacuum state.

Prior to deposition, a deposition material 20 to be deposited on the substrate 10 is arranged on the planarization layer 130 of FIG. 1. The substrate 10 is disposed to face the deposition material 20 that is arranged on the planarization layer 130. The substrate 10 is spaced apart from the deposition material 20 by a distance d. The distance d may be less than 1 mm. If the distance d is less than 1 mm, the chamber in which the deposition source 100 is to be disposed does not need to be kept in a high vacuum state and may be kept in a near vacuum state of about 10-2 torr, because a mean free path of the deposition material 20 is in inverse proportion to pressure.

The substrate 10 may be made out of transparent glass of which a main component is SiO2; however the substrate 10 is not limited thereto and may instead be made out of transparent plastics. The substrate 10 may be made out of a plastic insulating organic material that includes at least one of polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide, polycarbonate (PC), cellulose triacetate (TAC), and cellulose acetate propionate (CAP).

The substrate 10 may instead be made out of metal and include at least one of iron (Fe), chrominum (Cr), manganese (Mn), nickel (Ni), titanium (Ti), molybdenum (Mo), stainless steel (SUS), an Invar alloy, an Inconel alloy, and a Kovar alloy, however, the present invention is not limited thereto. When metal is used for the substrate, the substrate 10 may be foil-shaped.

A buffer layer (not shown) may be formed on a top surface of the substrate 10 so as to obtain a smooth top surface of the substrate 10 and to prevent impure elements from penetrating into the substrate 10. The buffer layer may be made out of SiO2 or SiNx.

The first electrode 11 is disposed on the substrate 10. The first electrode 11 may have a predetermined pattern that is produced by photolithography. In a passive matrix (PM) organic light-emitting device, the patterns of the first electrode 11 may be formed as striped lines that are spaced apart from one another by a predetermined distance. In an active matrix (AM) organic light-emitting device, the patterns of the first electrode 11 may be formed to correspond to pixels.

The first electrode 11 may be a reflection electrode or a transmission electrode. When the first electrode 11 is a reflection electrode, after a reflection layer made out of one or more of silver (Ag), magnesium (Mg), aluminum (Al), platinum (Pt), palladium (Pd), gold (Au), nickel (Ni), neodymium (Nd), iridium (Ir), chromium (Cr), lithium (Li), and calcium (Ca) and combinations thereof is deposited, indium tin oxide (ITO), indium zinc oxide (IZO), zinc oxide (ZnO) or In2O3 having a large work function is arranged on the reflection layer to complete formation of the first electrode 11.

When the first electrode 11 is a transmission electrode, the first electrode 11 is made out of one of ITO, IZO, ZnO or In2O3 having a large work function.

Referring to FIG. 10C, a hole injection layer 12 and a hole transport layer 13, which are organic layers commonly arranged on the first electrode 11, are formed on the substrate 10 using the deposition source 100. The hole injection layer 12 and the hole transport layer 13 function as a common layer in each pixel. Thus, a deposition process may be performed without an additional mask.

In this case, the deposition material 20 illustrated in FIG. 10A is a deposition material that is used to form the hole injection layer 12. After the hole injection layer 12 is formed, the deposition material 20 that remains on the planarization layer 130 is removed. Then, deposition material 20 that is used to form the hole transport layer 13 is put on the planarization layer 130, and the deposition process is performed so that the hole transport layer 13 is deposited onto the hole injection layer 12.

Referring to FIG. 10D, an organic light-emitting layer 14 is formed on the hole transport layer 13. The organic light-emitting layer 14 is formed using material that emits visible rays corresponding to red, green, and blue. In this case, a mask is disposed on the deposition source 100, and the organic light-emitting layer 14 that emits red visible rays may be produced by performing the deposition process at one time, and then, the organic light-emitting layer 14 that emits green visible rays and the organic light-emitting layer 14 that emits blue visible rays may be produced sequentially in the same manner as described, however, the present invention is not limited thereto, and the organic light-emitting layer 14 may be produced using an additional deposition device.

Also, when the organic light-emitting layer 14 that emits white visible rays that are used in illumination is produced, the red, green, and blue organic light-emitting layers 14 may be sequentially formed without an additional mask.

In the present embodiment, the deposition source 100 is larger than the substrate 10. Thus, a desired deposited film may be formed by performing the deposition process at one time while not moving either the substrate 10 or the deposition source 100.

Referring to FIG. 10E, an electron transport layer 15 and an electron injection layer 16 that are commonly arranged on the organic light-emitting layer 14 are produced. The electron transport layer 15 and the electron injection layer 16 function as a common layer for each pixel. Thus, the deposition process may be performed without an additional mask. A process of forming the electron transport layer 15 and the electron injection layer 16 is similar to the above-described process of forming the hole injection layer 12 and the hole transport layer 13, and thus, a description thereof will be omitted.

In the present embodiment, the hole injection layer 12, the hole transport layer 13, the electron transport layer 15, and the electron injection layer 16 are formed, however, the present invention is not limited thereto. As a result, at least one of the hole injection layer 12, the hole transport layer 13, the electron transport layer 15, and the electron injection layer 16 is produced for an organic light-emitting device 18.

Also, there is no limitation as to the deposition material 20 for forming the hole injection layer 12, the hole transport layer 13, the electron transport layer 15, and the electron injection layer 16. The deposition material 20 may be copper phthalocyanine (CuPc), N,N′-Di(naphthalene-1-yl)-N,N′-diphenyl-benzidine (NPB), tris-8-hydroxyquinoline aluminum (Alq3), poly-(2,4)-ethylene-dihydroxy thiophene (PEDOT) or polyaniline (PANI).

Referring to FIG. 10F, a second electrode 17 is disposed on the electron injection layer 16 so as to complete the manufacture of an organic light-emitting device 18.

For a PM organic light-emitting device, the second electrode 17 may be formed in striped patterns that are perpendicular to the patterns of the first electrode 11, and for an AM organic light-emitting device, the second electrode 17 may be formed over an active region in which an image is to be formed.

The second electrode 17 may be a transmission electrode or a reflection electrode. If the second electrode 17 is a transmission electrode, after metal having a small work function, i.e., Ag, Mg, Al, Pt, Pd, Au, Ni, Nd, Ir, Cr, Li, and Ca and combinations thereof are deposited on the substrate 10, an auxiliary electrode layer or a bus electrode line may be made out of a transparent conductive material such as ITO, IZO, ZnO or In2O3.

If the second electrode 17 is a reflection electrode, the second electrode 17 may be made out of metal having a small work function, i.e., Ag, Mg, Al, Pt, Pd, Au, Ni, Nd, Ir, Cr, Li, and Ca. The present embodiment is described on the assumption that the first electrode 11 is an anode and the second electrode 17 is a cathode, however, the polarities of the first electrode 11 and the second electrode 17 may be opposite.

A sealing member (not shown) may be disposed to face one surface of the substrate 10. The sealing member is formed to protect the organic light-emitting device 18 from external moisture or oxygen. The sealing member is made out of a transparent material. To this end, the sealing member may be made out of glass, plastics or a combination of an organic material and an inorganic material.

As described above, in a deposition source and a method of manufacturing an organic light-emitting device according to the present invention, deposition characteristics and uniformity of a deposited film can be improved.

While the present invention has been particularly shown and described ii with reference to exemplary embodiments thereof, it will be understood by those of ordinary skill in the art that various changes in form and details may be made therein without departing from the spirit and scope of the present invention as defined by the following claims.

What is claimed is:

1. A deposition source, comprising:
a heat source;
a heat transfer plate arranged on the heat source and adapted to receive heat generated by and transferred from the heat source; and
a planarization layer arranged on the heat transfer plate, the heat source to supply more heat per unit area to outer portions of the heat transfer plate that surrounds a central portion of the heat transfer plate than to the central portion of the heat transfer plate.

2. The deposition source of claim 1, wherein the heat source comprises a coil portion.

3. The deposition source of claim 2, further comprising a power supply unit, wherein the coil portion is comprised of a single body that is connected to the power supply unit.

4. The deposition source of claim 2, further comprising a plurality of power supply units, wherein the coil portion is comprised of a corresponding plurality of subcoil portions, and wherein ones of the plurality of subcoil portions are connected to separate and independent ones of the plurality of power supply units.

5. The deposition source of claim 2, wherein the coil portion is more compactly arranged in positions corresponding to the outer areas of the heat transfer plate that surround central areas of the hat transfer plate and are less compactly arranged in positions corresponding to the central areas of the heat transfer plate.

6. The deposition source of claim 4, wherein ones of the plurality of subcoil portions of the coil portion are arranged throughout an entirety of the heat transfer plate at a uniform density.

7. The deposition source of claim 2, wherein the coil portion is comprised of an element selected from a group consisting of nickel and titanium.

8. The deposition source of claim 1, wherein the heat source comprises a heat pipe and a heat transfer fluid arranged within the heat pipe.

9. The deposition source of claim 8, the heat pipe being comprised of a plurality of coils, wherein ones of the coils of the heat pipe are more compactly arranged at locations corresponding to an outer portion of the heat transfer plate that surrounds a central portion of the heat transfer plate and are less compactly arranged at locations corresponding to the central portion of the heat transfer plate.

10. The deposition source of claim 8, wherein the heat pipe is comprised an element selected from a group comprising copper and aluminum.

11. The deposition source of claim 8, wherein the heat transfer fluid is comprised of a paraffin-based compound.

12. The deposition source of claim 1, wherein the heat transfer plate is comprised of a metal.

13. The deposition source of claim I, wherein the planarization layer is separable from the heat transfer plate.

14. The deposition source of claim 1, wherein the planarization layer is comprised of an element selected from a group consisting of aluminum and copper.

15. The deposition source of claim 1, further comprising a heat blocking portion arranged to surround side surfaces of the heat transfer plate and the planarization layer.

16. The deposition source of claim 15, wherein portions of the heat blocking portion are arranged under the heat source.

17. The deposition source of claim 15, wherein the heat blocking portion comprises ceramic.

18. The deposition source of claim 15, wherein the heat blocking portion is comprised of at least one material selected from a group consisting of ZrO2, SiO2, and CaO.

19. The deposition source of claim 1, wherein a size of the planarization layer is larger than a size of a target on which the deposition material is to be deposited.

20. A method of manufacturing an organic light-emitting device, comprising:
providing a deposition source that includes a heat source, a heat transfer plate arranged on the heat source to receive heat generated by and transferred from the heat source, and a planarization layer arranged on the heat transfer plate, the heat source to supply more heat per unit area of the heat transfer plate to outer portions of the heat transfer plate that surround a central portion of the heat transfer plate than to the central portion of the heat transfer plate;
preparing a substrate having a first electrode arranged thereon;
forming an organic light-emitting layer on the first electrode;
forming at least one organic layer arranged adjacent to the organic light-emitting layer; and
forming a second electrode electrically connected to the organic light-emitting layer, wherein the deposition source is used to produce at least one of the organic light-emitting layer and the at least one organic layer.

21. The method of claim 20, wherein the forming of the at least one of the organic light-emitting layer and the at least one organic layer via the deposition source comprises arranging the substrate to face the planarization layer.

22. The method of claim 20, wherein a size of the planarization layer is larger than a size of the substrate.

23. The method of claim 20, wherein the at least one organic layer comprises at least one layer selected from a group consisting of a hole injection layer, a hole transport layer, an electron transport layer, and an electron injection layer.
